(19) United States
(12) Patent Application Publication
(10) Pub. No.: US 2009/0022958 A1
(43) Pub. Date: Jan. 22, 2009

(54) AMORPHOUS METAL-METALLOID ALLOY BARRIER LAYER FOR IC DEVICES

(76) Inventors: John J. Plombon, Portland, OR (US); Harsono S. Simka, Saratoga, CA (US); Adrien R. Lavoie, Beaverton, OR (US); Juan E. Dominguez, Hillsboro, OR (US)

Correspondence Address: INTEL CORPORATION;c/o INTELLEVATE, LLC, P.O. BOX 52050, MINNEAPOLIS, MN, 55402, US

(21) Appl. No.: 11/779,894

(22) Filed: Jul. 19, 2007

(51) Int. Cl. H01L 21/768; B32B 3/10

(52) U.S. Cl. 428/164; 438/653; 257/E21.575

(57) ABSTRACT

A method for fabricating an amorphous metal-metalloid alloy layer for use in an IC device comprises providing a substrate in a reactor that includes a dielectric layer having a trench, pulsing a metal precursor into the reactor to deposit within the trench, wherein the metal precursor is selected from the group consisting of CpTa(CO)₄, PDMAT, TBTDET, TaCl₅, Cp₂Co, Co-amidinates, Cp₂Ru, Ru-diketonates, and Ru(CO)₄, purging the reactor after the metal precursor pulse, pulsing a metalloid precursor into the reactor to react with the metal precursor and form an amorphous metal-metalloid alloy layer, wherein the metalloid precursor is selected from the group consisting of BH₃, BCl₃, catechol borane, AlMe₃, methylpyrrolidinealane, AICl₃, SiH₄, SiH₂Cl₂, SiCl₄, tetraalkylsilanes, GeH₄, GeH₂Cl₂, GeCl₄, SnCl₄, trialkylantimony, SbMe₃, SbEt₃, arsine, and trimethylarsine, purging the reactor after the metalloid precursor pulse, and annealing the amorphous metal-metalloid layer at a temperature between 50° C. and 700° C. for 5 to 1200 seconds.

### BACKGROUND

In the manufacture of integrated circuits, copper interconnects are generally formed on a semiconductor substrate using a copper dual damascene process. Such a process begins with a trench being etched into a dielectric layer and filled with a barrier layer, an adhesion layer, and a seed layer. A physical vapor deposition (PVD) process, such as a sputtering process, may be used to deposit a tantalum nitride (TaN) barrier layer and a tantalum (Ta) or ruthenium (Ru) adhesion layer (i.e., a TaN/Ta or TaN/Ru stack) into the trench. The TaN barrier layer prevents copper from diffusing into the underlying dielectric layer. The Ta or Ru adhesion layer is required because the subsequently deposited metals do not readily nucleate on the TaN barrier layer. This may be followed by a PVD sputter process to deposit a copper seed layer into the trench. An electroplating process is then used to fill the trench with copper metal to form the interconnect.

As device dimensions scale down, the aspect ratio of the trench becomes more aggressive as the trench becomes narrower. The line-of-sight PVD process gives rise to issues such as trench overhang of the barrier, adhesion, and seed layers, leading to pinched-off trench and via openings during plating and inadequate gapfill. Additionally, for very thin films (e.g., less than 5 nm thick) on patterned structures, thickness and composition control in PVD is difficult. For very thin layers, much less material is deposited onto the feature sidewalls compared to on the field regions.

One approach to addressing these issues is to reduce the thickness of the TaN/Ta or TaN/Ru stack, which widens the available gap for subsequent metallization. Unfortunately, this is often limited by the non-conformal characteristic of PVD deposition techniques. Accordingly, alternative techniques for depositing the barrier, adhesion, and seed layers are needed.

### BRIEF DESCRIPTION OF THE DRAWINGS

FIG. 1 illustrates a metal interconnect having an amorphous barrier layer in accordance with implementations of the invention.

FIG. 2 is a method of forming an amorphous barrier layer in accordance with implementations of the invention.

### DETAILED DESCRIPTION

Described herein are systems and methods of preventing metal from diffusing out of interconnects used in integrated circuit devices. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention provide amorphous barrier layers for use in integrated circuit applications. More specifically, in a dual damascene process for fabricating metal interconnects, the amorphous alloy layer of the invention may be used in place of conventional barrier layers that generally consist of metals such as tantalum and/or metal nitrides such as tantalum nitride, tungsten nitride, or titanium nitride. In some implementations of the invention, the amorphous barrier layer may consist of a metal-metalloid alloy layer where a metal such as tantalum, titanium, ruthenium, cobalt, palladium, tungsten, or platinum is alloyed with a metalloid such as boron, aluminum, silicon, germanium, tin, arsenic, antimony, tellurium, or polonium. In further implementations, the metal may be alloyed with an element that is not technically a metalloid but that may, under some circumstances, exhibit some metalloid behavior such as carbon, nitrogen, or iodine.

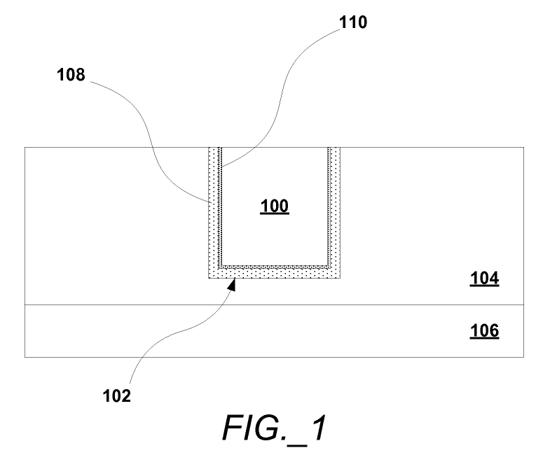

FIG. 1 illustrates a copper interconnect 100 formed within a trench 102 of a dielectric layer 104 upon a substrate 106. The copper interconnect 100 is located within metallization layers of an integrated circuit (IC) die and is used to interconnect transistors and other devices. The substrate 106 may be a portion of a semiconductor wafer. The dielectric layer 104 may be formed using conventional dielectric materials including, but not limited to, oxides such as silicon dioxide (SiO₂) and carbon doped oxide (CDO), silicon nitride, organic polymers such as perfluorocyclobutane (PFCB), and fluorosilicate glass (FSG).

In accordance with implementations of the invention, an amorphous metal-metalloid alloy barrier layer 108 and a metal adhesion layer 110 are formed between the copper interconnect 100 and the dielectric layer 104. In some implementations, the metal-metalloid alloy barrier layer 108 may be homogenous across its thickness, in other words, the ratio of metal-to-metalloid may be homogenous throughout the metal-metalloid barrier layer 108. In further implementations, the metal-metalloid barrier layer 108 may be a graded layer where the ratio of metal-to-metalloid varies across its thickness. The thickness of the metal-metalloid barrier layer 108 may range from around 1 nanometer (nm) to around 10 nm.

In accordance with the invention, novel precursors are used in a plasma-enhanced atomic layer deposition (PEALD) process to form the amorphous metal-metalloid alloy barrier layer. These include precursors for metals such as tantalum, titanium, ruthenium, cobalt, palladium, tungsten, and platinum, precursors for metalloids such as boron, aluminum, silicon, germanium, tin, arsenic, antimony, tellurium, and polonium, as well as precursors for carbon, nitrogen, and iodine.

Regarding the metal precursors, tantalum (Ta) precursors include, but are not limited to, CpTa(CO)₄ (where Cp=cyclopentadienyl), pentakis-(dimethylamido)tantalum (PDMAT), terbutylimido tris(diethylamido)tantalum (TBTDET), and TaCl₅. Cobalt (Co) precursors include, but are not limited to, Cp₂Co and Co-amidinates. Ruthenium (Ru) precursors include, but are not limited to, Cp₂Ru, Ru-diketonates, and Ru₃(CO)₁₂.

Regarding the metalloid precursors, boron (B) precursors include, but are not limited to, BH₃, BCl₃, and catechol borane. Aluminum (Al) precursors include, but are not limited to, AlMe₃ (where Me=methyl), pyrrolidinealane, and AlCl₃. Silicon (Si) precursors include, but are not limited to, SiH₄, SiCl₄, and tetraalkylsilanes. Germanium (Ge) precursors include, but are not limited to, GeH₄ and GeCl₄. Antimony (Sb) precursors include, but are not limited to, trialkylantimony, SbMe₃, and SbEt₃ (where Et=ethyl). Arsenic precursors include, but are not limited to, arsine and trimethylarsine.

Additional precursors that may be used in implementations of the invention include, but are not limited to, ethyl iodine (C₂H₅I), C₂H₃I, iodomethane (CH₃₁), diiodomethane (CH₂I₂), triiodomethane (CH₃₁), nitrogen (N₂), ammonia (NH₃), ammonium chloride (NH₄Cl), methane (CH₄), and ethane (C₂H₆).

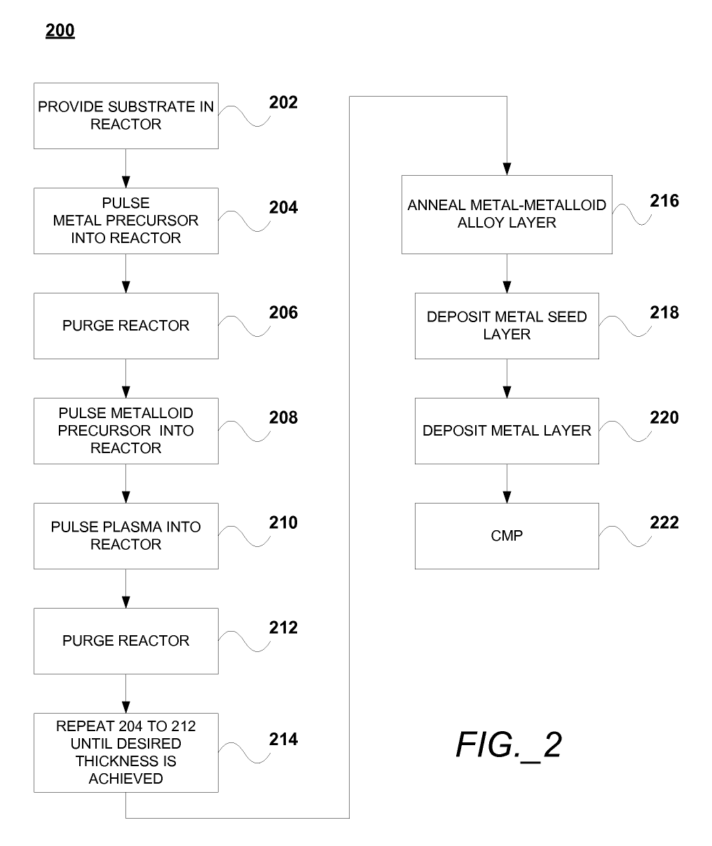

FIG. 2 is a method 200 for fabricating an amorphous metal-metalloid alloy barrier layer and a metal interconnect in accordance with an implementation of the invention. The method 200 begins by providing a semiconductor substrate onto which the metal-metalloid alloy layer and the metal interconnect may be formed (process 202 of FIG. 2). The semiconductor substrate may be formed using a bulk silicon or a silicon-on-insulator substructure. In other implementations, the substrate may be formed using alternate materials, which may or may not be combined with silicon, that include but are not limited to germanium, indium antimonide, lead telluride, indium arsenide, indium phosphide, gallium arsenide, gallium antimonide, or other Group III-V materials. Although a few examples of materials from which the semiconductor substrate may be formed are described here, any material that may serve as a foundation upon which a semiconductor device may be built falls within the spirit and scope of the present invention.

The substrate has at least one dielectric layer deposited on its surface. The dielectric layer may be formed using materials known for the applicability in dielectric layers for integrated circuit structures, such as low-k dielectric materials. Such dielectric materials include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The dielectric layer may include pores or other voids to further reduce its dielectric constant. The dielectric layer may include one or more trenches and/or vias within which the metal-metalloid alloy layer and the metal interconnect will be formed. The trenches and/or vias may be patterned using conventional wet or dry etch techniques that are known in the art.

The substrate may be housed in a reactor in preparation for a chemical vapor deposition process, such as a PEALD process. The substrate may be heated within the reactor to a temperature between around 25° C. and around 350° C. The pressure within the reactor may range from 0.01 Torr to 5.0 Torr.

One or more atomic layer deposition (ALD) process cycles are then carried out to deposit a metal-metalloid alloy layer. The ALD process cycle begins by introducing at least one pulse of a metal precursor into the reactor (204). At least one of the metal precursors described above may be used here, including but not limited to precursors that contain tantalum, titanium, ruthenium, cobalt, palladium, tungsten, or platinum. In various implementations of the invention, the following process parameters may be used for the metal precursor pulse. The metal precursor pulse may have a duration that ranges from around 0.1 seconds to around 10 seconds with a flow rate of up to 10 standard liters per minute (SLM). The specific number of metal precursor pulses may range from 1 pulse to 200 pulses or more depending on the desired thickness of the final metal-metalloid alloy layer. The metal precursor temperature may be between around 60° C. and 250° C. The vaporizer temperature may be around 60° C. to around 250° C.

A heated carrier gas may be employed to move the metal precursor, with a temperature that generally ranges from around 50° C. to around 200° C. Carrier gases that may be used here include, but are not limited to, argon (Ar), xenon (Xe), helium (He), hydrogen (H₂), nitrogen (N₂), forming gas, or a mixture of these gases. The flow rate of the carrier gas may range from around 100 SCCM to around 700 SCCM.

The precursor delivery line into the reactor may be heated to a temperature that ranges from around 60° C. to around 250° C., or alternately, to a temperature that is at least 25° C. hotter than the volatile precursor flow temperature within the delivery line to avoid condensation of the precursor. Before discharge, the delivery line pressure may be set to around 0 to 5 psi, the orifice may be between 0.1 mm and 1.0 mm in diameter, and the charge pulse may be between 0.5 seconds and 5 seconds. The equilibration time with the valves closed may be 0.5 seconds to 5 seconds and the discharge pulse may be 0.5 seconds to 5 seconds.

An RF energy source may be during the alloy metal precursor pulse at a power that ranges from 5 W to 1000 W and at a frequency of 13.56 MHz, 27 MHz, or 60 MHz. It should be noted that the scope of the invention includes any possible set of process parameters that may be used to carry out the implementations of the invention described herein.

After the at least one pulse of the metal precursor, the ALD process cycle purges the reactor (206). The purge gas may be an inert gas such as Ar, Xe, N₂, He, or forming gas and the duration of the purge may range from 0.1 seconds to 60 seconds, depending on the PEALD reactor configurations and other deposition conditions. In most implementations of the invention, the purge may range from 0.5 seconds to 10 seconds.

In accordance with implementations of the invention, the ALD process continues by introducing at least one pulse of a metalloid precursor into the reactor as a co-reactant to react with the metal precursor (208). At least one of the metalloid precursors described above may be used here, including but not limited to precursors that contain boron, aluminum, silicon, germanium, tin, arsenic, antimony, tellurium, polonium, carbon, nitrogen, or iodine. In some implementations, the metalloid precursor may be added using a physical vapor deposition process and a target containing the desired metalloid. Process parameters similar to those provided above may be used for the co-reactant pulse, although the number of metalloid precursor pulses will generally be much lower than the number of metal precursor pulses since the metalloid is incorporated at low concentrations in accordance with implementations of the invention.

For instance, in implementations of the invention, the process parameters for the metalloid precursor pulse include a pulse duration of between around 0.5 seconds and 10 seconds at a flow rate of up to 10 SLM, where the specific number of metalloid precursor pulses may range from 1 pulse to 200 pulses or more depending on the desired concentration of metalloid in the final metal-metalloid alloy layer. The number of metalloid precursor pulses is generally dependent on the number of metal precursor pulses used. For example, given the number of metal precursor pulses used above, the number of metalloid precursor pulses necessary to produce a metalloid concentration in the final alloy layer that is between around 0.1% and around 50% may be calculated and used.

A carrier gas may be employed to move the metalloid precursor. Carrier gases that may be used here include, but are not limited to, Ar, Xe, He, H₂, N₂, forming gas, or a mixture of these gases. The flow rate of the carrier gas may range from around 100 SCCM to around 700 SCCM. The metalloid precursor temperature may be between around 60° C. and 250° C. An RF energy source may be applied as described above. It should be noted that the scope of the invention includes any possible set of process parameters that may be used to carry out the implementations of the invention described herein.

In some implementations of the invention, an optional plasma, such as an argon plasma, may be applied during the one or more metalloid precursor pulses (210). The plasma may be used to disassociate the metalloid element from the rest of the precursor, thereby freeing the metalloid element and allowing it to become incorporated into a metal-metalloid alloy layer. In implementations where a plasma is used, process parameters that may be used for the plasma include a flow rate of around 200 SCCM to around 600 SCCM. The plasma may be pulsed into the reactor with a pulse duration of around 0.5 seconds to around 10.0 seconds, with a pulse duration of around 1 to 4 seconds often being used. The plasma power may range from around 20 W to around 1000 W and will generally range from around 60 W to around 700 W. A carrier gas such as He, Ar, or Xe may be used to introduce the plasma. A chuck upon which the semiconductor substrate is mounted may be biased and capacitively-coupled.

After the at least one pulse of the metalloid precursor, the ALD process purges the reactor (212). The purge gas may be an inert gas such as Ar, Xe, N₂, He, or forming gas and the duration of the purge may range from 0.1 seconds to 60 seconds, depending on the PEALD reactor configurations and other deposition conditions. In most implementations of the invention, the purge may range from 0.5 seconds to 10 seconds. Here, the purge removes excess metalloid precursor as well as by-products from the reaction between the metal precursor and the metalloid precursor.

The above processes result in the formation of a metal-metalloid alloy layer on the substrate within a trench of the dielectric layer. If the metal-metalloid alloy layer has not yet reached a desired thickness, the above ALD process cycle may be repeated as necessary until the desired thickness is achieved (214).

The metal-metalloid alloy layer produced is an amorphous layer that provides a barrier to metal diffusion. For instance, if the appropriate precursors are selected from the list above to produce a tantalum carbide (TaC) layer, the TaC layer will have an intentional carbon incorporation from a covalent bond resulting in a single phase barrier. If the carbon had been incorporated as an impurity, the result would be two different materials and phases that would result in a material with poor mechanical rigidity and inferior barrier properties that would permit for “grain boundary” type copper diffusion. Contrary to this, the amorphous TaC layer produced in accordance with the invention is a strong barrier to metal diffusion.

The metalloid element may be precisely controlled by way of the ALD processing. For instance, the concentration of metalloid in the alloy barrier layer may be precisely controlled by varying the number of metalloid precursor pulses used in the deposition process. The concentration may be varied across the thickness of the alloy barrier layer by appropriately adjusting the number of metalloid precursor pulses in successive ALD process cycles. If the metalloid consists of aluminum, the aluminum concentration in the alloy layer may be graded to provide a barrier to electromigration.

In further implementations of the invention, the metal-metalloid alloy layer may be further tailored to have a specific composition by manipulating process parameters during the deposition process. Process parameters that may be manipulated to establish a metal concentration gradient and/or a metalloid concentration gradient within the alloy layer include, but are not limited to, the specific precursors that are used in each process cycle, how long each precursor is flowed into the reactor during a process cycle, the precursor concentration and flow rate during each process cycle, the co-reactant used, how long each co-reactant is flowed into the reactor during a process cycle, the co-reactant concentration and flow rate during each process cycle, the sequence or order of the precursor and co-reactant, the plasma energy applied, the substrate temperature, the pressure within the reaction chamber, and the carrier gas composition. Furthermore, changing the parameters of each individual process cycle, or groups of successive process cycles, may also be used to tailor the metal-metalloid alloy layer.

After the ALD process cycles used to form the metal-metalloid alloy layer are complete, an annealing process may be used to further incorporate the metalloid element into the alloy layer (216). In accordance with implementations of the invention, the anneal may take place at a temperature between around 50° C. and around 700° C. for a time duration that may last from 5 seconds to 1200 seconds. Because the amorphous metal-metalloid alloy layer may become crystalline at temperatures over 700° C., the anneal will generally occur at temperatures below 400° C. In some implementations, the anneal may take place in an oxygen free ambient atmosphere, such as forming gas or a pure inert gas. In some implementations, the annealing process may be carried out after a metal interconnect has been formed on the metal-metalloid alloy barrier layer.

In accordance with some implementations of the invention, one or more ALD process cycles may be used to deposit a metal seed layer, such as a copper seed layer, atop the metal-metalloid alloy barrier layer (218). The same reactor may be used for this ALD process. Copper metal precursors that may be used to form a conventional copper seed layer, as well as the required co-reactants and process parameters, are well known in the art. The ALD process to form the metal seed layer may be repeated as necessary to produce a metal seed layer having a sufficient thickness.

Following the fabrication of the metal seed layer, the substrate may be transferred to a reactor containing a plating bath and a plating process may be carried out to deposit a metal layer, such as a copper layer, over the metal seed layer (220). The metal layer fills the trench to form the metal interconnect, generally a copper interconnect. In some implementations, the plating bath is an electroplating bath and the plating process is an electroplating process. In other implementations, the plating bath is an electroless plating bath and the plating process is an electroless plating process. In further implementations, alternate copper deposition processes may be used. Finally, a chemical mechanical polishing (CMP) process may be used to planarize the deposited copper metal and finalize the copper interconnect structure (222).

Accordingly, a process has been described for fabricating an amorphous metal-metalloid alloy layer that may be used as a barrier layer for metal interconnects in integrated circuit applications. An ALD process flow is used with metal precursors and metalloid precursors to form the amorphous alloy layer of the invention. The concentration of the metalloid element in the alloy layer is relatively low. The result is a conformal barrier layer that may be used in trenches with aggressive aspect ratios to reduce trench overhang and pinch-off risks.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
providing a substrate in a reactor;
pulsing a metal-containing precursor into the reactor to deposit on the substrate;
purging the reactor after the metal-containing precursor pulse;
pulsing a metalloid-containing precursor into the reactor to react with the metal-containing precursor and form an amorphous metal-metalloid alloy layer; and
purging the reactor after the metalloid-containing precursor pulse.

2. The method of claim 1, wherein the metal-containing precursor is selected from the group consisting of CpTa(CO)₄, PDMAT, TBTDET, TaCl₅, Cp₂Co, Co-amidinates, Cp₂Ru, Ru-diketonates, and Ru₃(CO)₁₂.

3. The method of claim 1, wherein the metalloid-containing precursor is selected from the group consisting of BH₃, BCl₃, catechol borane, AlMe₃, methylpyrrolidinealane, AICl₃, SiH₄, SiH₂Cl₂, SiCl₄, tetraalkylsilanes, GeH₄, GeH₂Cl₂, GeCl₄, SnCl₄, trialkylantimony, SbMe₃, SbEt₃, arsine, and trimethylarsine.

4. The method of claim 1, further comprising annealing the amorphous metal-metalloid alloy layer.

5. The method of claim 4, wherein the annealing process occurs at a temperature between 50° C. and 700° C. for a time duration between 5 seconds and 1200 seconds.

6. The method of claim 1, wherein the pulsing of the metal-containing precursor, the purging after the metal-containing precursor pulse, the pulsing of the metalloid-containing precursor, and the purging after the metalloid-containing precursor are repeated until the amorphous metal-metalloid alloy layer reaches a desired thickness.

7. The method of claim 6, wherein the amount of metalloid-containing precursor pulsed into the reactor in successive pulses is varied to cause the amorphous metal-metalloid alloy layer to have a variable metalloid concentration across its thickness.

8. The method of claim 1, wherein a sufficient amount of the metalloid-containing precursor is pulsed into the reactor to fabricate an amorphous metal-metalloid alloy layer having a metalloid concentration that is between around 0.1% and around 50%.

9. The method of claim 1, further comprising:
depositing a metal seed layer on the amorphous metal-metalloid alloy layer using an ALD process; and
depositing a metal layer on the metal seed layer using a plating process.

10. The method of claim 9, wherein the metal comprises copper.

11. A method comprising:
providing a substrate in a reactor, wherein the substrate includes a dielectric layer having a trench;
pulsing a metal-containing precursor into the reactor to deposit within the trench, wherein the metal-containing precursor is selected from the group consisting of CpTa(CO)₄, PDMAT, TBTDET, TaCl₅, Cp₂Co, Co-amidinates, Cp₂Ru, Ru-diketonates, and Ru(CO)₄;
purging the reactor after the metal-containing precursor pulse;
pulsing a metalloid-containing precursor into the reactor to react with the metal-containing precursor and form an amorphous metal-metalloid alloy layer within the trench, wherein the metalloid-containing precursor is selected from the group consisting of BH₃, BCl₃, catechol borane, AlMe₃, methylpyrrolidinealane, AICl₃, SiH₄, SiH₂Cl₂, SiCl₄, tetraalkylsilanes, GeH₄, GeH₂Cl₂, GeCl₄, SnCl₄, trialkylantimony, SbMe₃, SbEt₃, arsine, and trimethylarsine;
purging the reactor after the metalloid-containing precursor pulse; and
annealing the amorphous metal-metalloid alloy layer at a temperature between 50° C. and 700° C. for a time duration between 5 seconds and 1200 seconds.

12. The method of claim 11, wherein the pulsing of the metal-containing precursor, the purging after the metal-containing precursor pulse, the pulsing of the metalloid-containing precursor, and the purging after the metalloid-containing precursor are repeated until the amorphous metal-metalloid alloy layer reaches a desired thickness.

13. The method of claim 12, wherein the amount of metalloid-containing precursor pulsed into the reactor in successive pulses is varied to cause the amorphous metal-metalloid alloy layer to have a variable metalloid concentration across its thickness.

14. The method of claim 11, wherein a sufficient amount of the metalloid-containing precursor is pulsed into the reactor to fabricate an amorphous metal-metalloid alloy layer having a metalloid concentration that is between around 0.1% and around 50%.

15. An apparatus comprising:
a substrate having a dielectric layer formed thereon and a trench etched into the dielectric layer;
an amorphous metal-metalloid alloy layer formed on a bottom surface and sidewalls of the trench; and
a copper layer formed on the amorphous metal-metalloid alloy layer within the trench.

16. The apparatus of claim 15, wherein the substrate comprises a bulk silicon structure or a silicon-on-insulator structure.

17. The apparatus of claim 16, wherein the substrate further includes germanium, indium antimonide, lead telluride, indium arsenide, indium phosphide, gallium arsenide, gallium antimonide, or a Group III-V material.

18. The apparatus of claim 15, wherein the amorphous metal-metalloid alloy layer comprises:
a metal selected from the group consisting of tantalum, titanium, ruthenium, cobalt, palladium, tungsten, and platinum; and
a metalloid selected from the group consisting of boron, aluminum, silicon, germanium, arsenic, antimony, tellurium, polonium, carbon, nitrogen, and iodine.

19. The apparatus of claim 15, wherein the amorphous metal-metalloid alloy layer has a thickness between around 1 nm and around 10 nm.

20. The apparatus of claim 15, wherein the copper layer comprises a copper seed layer and a copper layer formed on the copper seed layer.
